(19) United States
(12) Patent Application Publication
(10) Pub. No.: US 2008/0197374 A1
(43) Pub. Date: Aug. 21, 2008

(54) High-power light-emitting diode

(76) Inventor: Wen-Kung Sung, Taipei City (TW)

Correspondence Address: TROXELL LAW OFFICE PLLC, SUITE 1404, 5205 LEESBURG PIKE, FALLS CHURCH, VA, 22041, US

(21) Appl. No.: 11/706,427

(22) Filed: Feb. 15, 2007

(51) Int. Cl. H01L 33/00

(52) U.S. Cl. 257/99; 257/E33.001

(57) ABSTRACT

A high-power light-emitting diode comprises a pillar, at least one light-emitting chip, a substrate, at least two conducting wires, and a transparent layer. The pillar has an integrally cast structure. The pillar has a block on which a recessed cup is formed. In addition, a screw bolt is extended from a lower portion of the block. The light-emitting chip is mounted on the inside of the recessed cup formed on the block of the pillar. Two conducting layers are mounted on the substrate. The substrate is located to encircle the recessed cup on the block. The light-emitting chip is connected with the substrate via these two conducting wires. The recessed cup, the light-emitting chip, and the substrate are covered with the transparent layer. Accordingly, the heat energy can be dissipated quickly and the product can be assembled easily.

### FIELD OF THE INVENTION

The present invention relates to an easily-assemblable high-power light-emitting diode (LED) to dissipate heat energy quickly, wherein the high-power light-emitting diode is applicable to projection lamps, car lamps, illumination lamps, flashlights or the likes.

### BACKGROUND OF THE INVENTION

With the evolution of modern light-emitting diode industry, the light-emitting diode has a wide variety of applications, wherein the conventional light bulbs are gradually replaced by the light-emitting diodes in various fields. In former days, the light-emitting diode was always applied to the electronic devices. However, the modern light-emitting diode capable of emitting light of different colors by the crystal layer is much brighter than before and almost provides the required brightness in daily life.

In order to increase the brightness of the light-emitting diode, the high power voltage must be utilized. However, the use of high power voltage is accompanied by the problem of heat energy accumulation. Because the heat energy generated by the light-emitting diode can not be dissipated, the chip is burned out easily after a short period of use. As a result, a heat-dissipation device must be attached to the conventional high-power light-emitting diode to reduce the temperature and to prevent the chip from burnout.

In view of the foregoing description, the motive of the present invention is to provide the general public with an easily-assemblable high-power light-emitting diode to dissipate the heat energy quickly.

### SUMMARY OF THE INVENTION

A major object of the present invention is to provide a high-power light-emitting diode having an integrally cast copper pillar for dissipating and reducing the heat energy quickly.

Another object of the present invention is to provide an easy-to-assemble high-power light-emitting diode.

A further object of the present invention is to provide a high-power light-emitting diode for reducing the manufacture cost significantly.

In order to achieve the above-mentioned object, a high-power light-emitting diode is comprised of a pillar, at least one light-emitting chip, a substrate, at least two conducting wires, and a transparent layer. The pillar has an integrally cast structure. The pillar has a block on which a recessed cup is formed. In addition, a screw bolt is extended from a lower portion of the block. The light-emitting chip is mounted on the inside of the recessed cup formed on the block of the pillar. Two conducting layers are mounted on the substrate. The substrate is located to encircle the recessed cup on the block. The light-emitting chip is connected with the substrate via these two conducting wires. The recessed cup, the light-emitting chip, and the substrate are covered with the transparent layer. Accordingly, the heat energy can be dissipated quickly and the product can be assembled easily.

The aforementioned object and other advantages of the present invention will be readily clarified in the description of the preferred embodiments and the enclosed drawings of the present invention.

### BRIEF DESCRIPTION OF THE DRAWINGS

FIG. 1 is an elevational view showing a first preferred embodiment of the present invention.

FIG. 2 is a cross-sectional view of the present invention.

FIG. 3 is a top view of the present invention.

FIG. 4 is a cross-sectional view showing a second preferred embodiment of the present invention.

FIG. 5 is a cross-sectional view showing a third preferred embodiment of the present invention.

### DETAILED DESCRIPTION OF THE PREFERRED EMBODIMENT

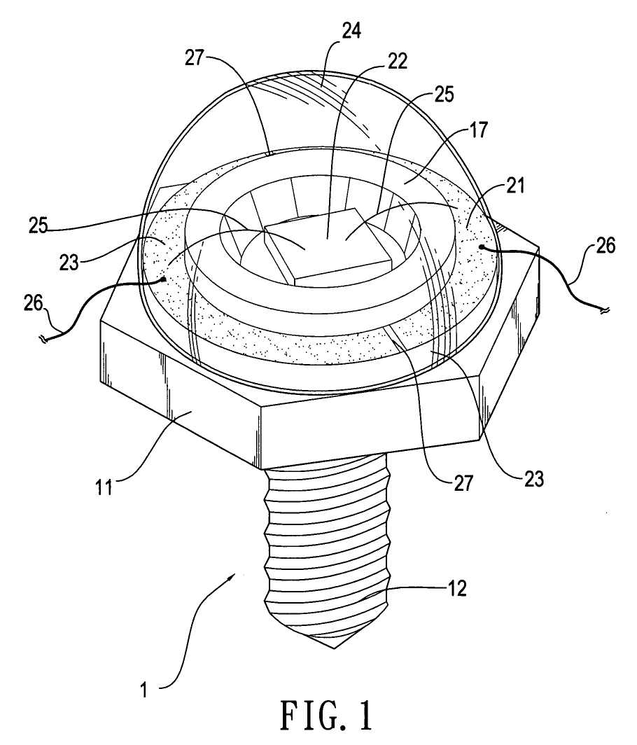

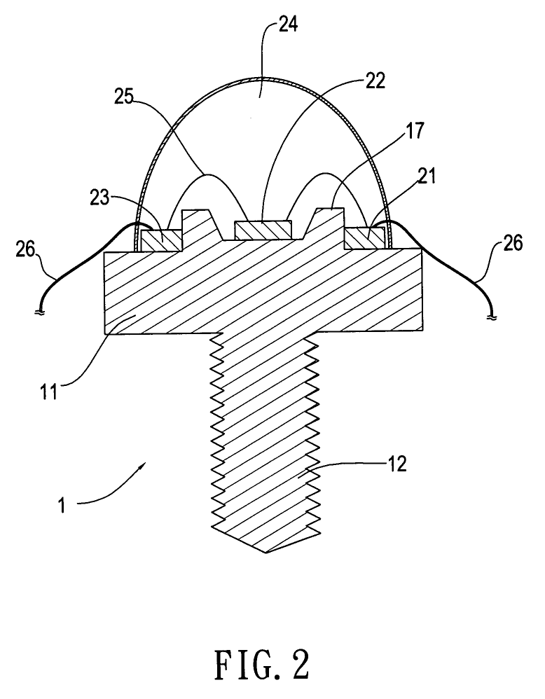

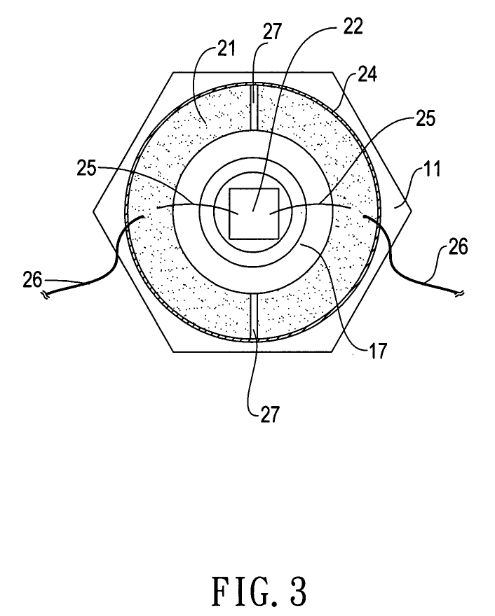

Referring to FIGS. 1 through 3, a high-power light-emitting diode in accordance with a first preferred embodiment of the present invention comprises a pillar 1, at least one light-emitting chip 22, a substrate 23, at least two connection wires 25, and a transparent layer 24, wherein the pillar 1 has an integrally cast structure made of copper or other heat-dissipation material. The pillar 1 has a hexagonal, octagonal, or polygonal block 11. In addition, a recessed cup 17 is formed on the block 11. A screw bolt 12 is extended from the lower portion of the block 11. The light-emitting chip 22 is attached to inside of the recessed cup 17 formed on the block 11 of the pillar 1, wherein the recessed cup 17 has a planar bottom. Two conducting layers 21 are mounted on the substrate 23. An insulation tunnel 27 is formed between these two conducting layers 21 to avoid electrical connection therebetween. Two polarized leads 26 are connected to these two conducting layers 21 for providing electrical series connection. The substrate 23 is located to encircle the recessed cup 17 on the block 11. The substrate 23 is electrically connected to the light-emitting chip 22 via these two conducting wires 25 so as to electrify the light-emitting chip 22 for generating the light. In addition, the recessed cup 17, the light-emitting chip 22, and the substrate 23 are covered with the transparent layer 24, wherein the transparent layer 24 is a resin layer such as epoxy resin or silicone.

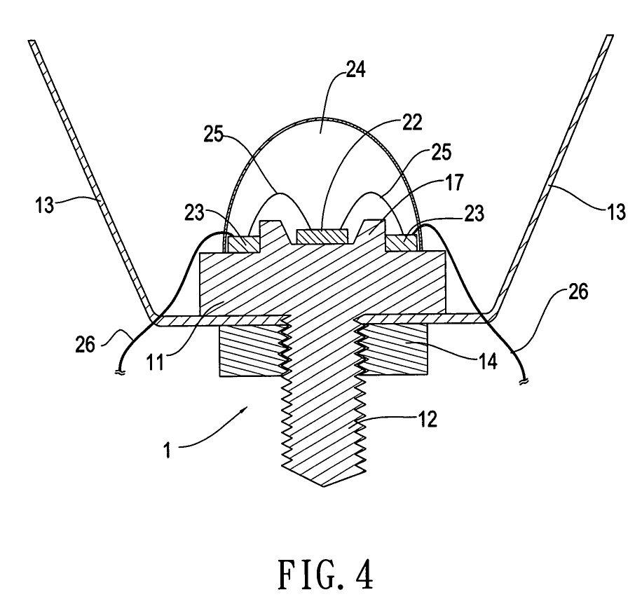

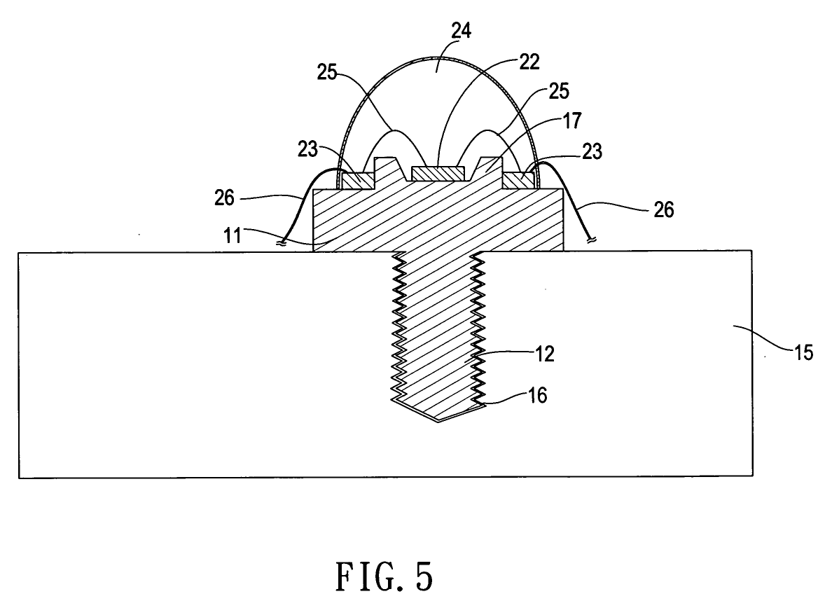

Referring to FIG. 4, a second preferred embodiment of the present invention is shown. A condensing cover 13 is screwed onto the pillar 1. The condensing cover 13 is an aluminum foil for condensing the light and outward reflecting the light. In addition, the heat energy generated by the light-emitting chip 22 can be transferred to the aluminum condensing cover 13 rapidly by contacting the aluminum condensing cover 13 with the block 11 of the pillar 1. Accordingly, the heat energy generated by the light-emitting chip 22 can be dissipated rapidly for reducing the temperature so as to prevent the light-emitting chip 22 from overheating and burnout. In addition, a screw nut 14 can be screwed under the condensing cover 13 to improve the heat-dissipation effect. Referring to FIG. 5, a third preferred embodiment of the present invention is shown, wherein a threaded hole 16 is formed on any type of heat-dissipation plate 15 or heat sink so that the screw bolt 12 of the pillar 1 can be firmly screwed into the heat-dissipation plate 15. As a result, the heat energy generated by the light-emitting chip 22 can be transferred to the heat-dissipation plate 15 through the pillar 1 for dissipating the heat energy. In addition, the screw bolt 12 extending from the lower portion of the block 11 allows easy replacement and easy assembly.

In accordance with the foregoing description, the present invention has the following practical advantages:

1. The light-emitting chip is so closely coupled with the recessed cup of the pillar that the heat energy can be dissipated and reduced quickly through the pillar, and the pillar also allows the assembling and positioning processes to be performed easily.

2. The pillar has a hexagonal block for being firmly screwed into the heat-dissipation plate so that the heat energy generated by the light-emitting chip can be transferred to the heat-dissipation plate quickly via the pillar for improving the heat-dissipation effect.

3. The high-power light-emitting diode has a condensing cover screwed thereon so as to gather up the light beams emitted from the light-emitting diode and to dissipate the heat energy through the condensing cover.

In summary, the high-power light-emitting diode of the present invention indeed achieves the anticipated purposes. Accordingly, the present invention satisfies the requirement for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A high-power light-emitting diode comprising:
an integrally cast pillar having a block on which a recessed cup is formed and a screw bolt extending from a lower portion of said block;
at least one light-emitting chip mounted on the inside of said recessed cup formed on said block of said pillar;
a substrate on which two conducting layers are mounted, said substrate being located to encircle said recessed cup on said block;
at least two conducting wires for connecting said light-emitting chip with said substrate; and
a transparent layer for covering said recessed cup, said light-emitting chip, and said substrate so as to dissipate the heat energy quickly and to provide easy assembly.

2. A high-power light-emitting diode of claim 1, wherein said pillar is a copper pillar.

3. A high-power light-emitting diode of claim 1, further comprising a condensing cover screwed onto said pillar for condensing the light and outward reflecting the light.

4. A high-power light-emitting diode of claim 1, further comprising a heat-dissipation plate firmly screwed onto a lower portion of said pillar.

5. A high-power light-emitting diode of claim 1, further comprising two polarized leads connected to said conducting layers on said substrate for providing electrical series connection.

6. A high-power light-emitting diode of claim 1, wherein said transparent layer is a resin layer.
